(19) United States
(12) Patent Application Publication
(10) Pub. No.: US 2013/0247980 A1
(43) Pub. Date: Sep. 26, 2013

(54) METHOD FOR FABRICATING BACK ELECTRODE TYPE SOLAR CELL, AND BACK ELECTRODE TYPE SOLAR CELL

(71) Applicants: Yuhji Yokosawa, Osaka-shi (JP); Tsutomu Yamazaki, Osaka-shi (JP); Hiroyuki Akada, Osaka-shi (JP); Takayuki Isaka, Osaka-shi (JP)

(72) Inventors: Yuhji Yokosawa, Osaka-shi (JP); Tsutomu Yamazaki, Osaka-shi (JP); Hiroyuki Akada, Osaka-shi (JP); Takayuki Isaka, Osaka-shi (JP)

(73) Assignee: SHARP KABUSHIKI KAISHA, Osaka-shi, Osaka (JP)

(21) Appl. No.: 13/990,538

(22) PCT Filed: Dec. 2, 2011
(86) PCT No.: PCT/JP2011/077912

§ 371 Date: May 30, 2013

(30) Foreign Application Priority Data
Dec. 6, 2010 (JP) 2010-271134

(51) Int. Cl. H01L 31/0216

(52) U.S. Cl. CPC H01L 31/02168
USPC 136/256; 438/72

(57) ABSTRACT

A method for fabricating a back electrode type solar cell include the steps of applying a solution including a compound containing first conductivity type impurities, titanium alkoxide, and alcohol to a surface of a first conductivity type silicon substrate, and forming a light-receiving face diffusion layer and an anti-reflection film by subjecting the solution to heat treatment in a nitrogen atmosphere. There is also provided a back electrode type solar cell including a light-receiving face diffusion layer having a sheet resistance greater than or equal to 100 Ω/ and less than 250 Ω/.

### TECHNICAL FIELD

The present invention relates to a method for fabricating a back electrode type solar cell, and a back electrode type solar cell.

### BACKGROUND ART

In recent years, the potential for a solar cell that converts sunlight energy directly into electrical energy as the energy source for the next generation is rapidly expanding from the standpoint of global environmental issues. Although there are various types of solar cells such as those employing compound semiconductors and organic materials, the current mainstream is a solar cell employing silicon crystal.

Solar cells that are most fabricated and available on the market today are those based on a structure in which an electrode is formed each on the surface where sunlight enters (light-receiving face) and on the face at the side opposite to the light-receiving face (back face).

Since a solar cell with an electrode formed at the light-receiving face has the sunlight absorbed by the electrode, the amount of light incident on the light-receiving face of the solar cell will be reduced corresponding to the area on which the electrode is formed. Therefore, a back electrode type solar cell based on a structure in which the electrodes are formed only on the back face of the solar cell has been developed.

FIG. 10 represents a schematic sectional view of a conventional back electrode type solar cell disclosed in PTD 1 (Japanese National Patent Publication No. 2008-532311).

On the light-receiving face of a conventional back electrode type solar cell 101 shown in FIG. 10, an n type front face side diffusion region 106 is formed to constitute an FSF (Front Surface Field) structure. The light-receiving face of back electrode type solar cell 101 has a concavo-convex shape 105 on which are formed, from the side of an n type silicon wafer 104, a dielectric passivation layer 108 containing silicon dioxide and an anti-reflection coating 107 containing silicon nitride, in the cited order.

On the back face of n type silicon wafer 104, an n+ region 110 doped with n type impurities and a p+ region 111 doped with p type impurities are formed alternately. An oxide layer 109 is formed on the back face of n type silicon wafer 104. Furthermore, a metal contact for n type 102 is formed on n+ region 110 and a metal contact for p type 103 is formed on p+ region 111, at the back face of n type silicon wafer 104.

### CITATION LIST

### Patent Document

PTD 1: Japanese National Patent Publication No. 2008-532311

### SUMMARY OF INVENTION

### Technical Field

FIG. 11 is a flowchart of a fabrication method for conventional back electrode type solar cell 101 shown in FIG. 10, contemplating the light-receiving face side.

First, as shown in step S101, a concavo-convex shape 105 is formed at the light-receiving face of n type silicon wafer 104. As shown in step S102, n type impurities are diffused onto the light-receiving face of n type silicon wafer 104 to form n type front surface side diffusion region 106. Then, as shown in step S103, a dielectric passivation layer 108 is formed on n type front surface side diffusion region 106. As shown in step S104, an anti-reflection coating 107 is formed on dielectric passivation layer 108.

The method according to the flowchart of FIG. 11 is disadvantageous in that back electrode type solar cell 101 cannot be fabricated efficiently since there are many processing steps in the case where the structure of the light-receiving face side of back electrode type solar cell 101 is formed. There is also the problem that the property of back electrode type solar cell 101 is degraded due to the great amount of recombination current caused by the passivation at the light-receiving face side.

In view of the foregoing, an object of the present invention is to provide a method for fabricating a back electrode type solar cell allowing efficient production with a reduced number of steps, and allowing recombination current caused by passivation at the light-receiving face side to be reduced, and a back electrode type solar cell.

### Solution to Problem

The present invention is directed to a method for fabricating a back electrode type solar cell, comprising the steps of: applying a solution including a compound containing first conductivity type impurities, titanium alkoxide and alcohol to one surface of a first conductivity type silicon substrate; forming a light-receiving face diffusion layer at the surface of the silicon substrate and forming an anti-reflection film on the surface of the silicon substrate by subjecting the solution to a first heat treatment in a nitrogen atmosphere; and forming a light-receiving face passivation film on the surface of the silicon substrate by subjecting the surface of the silicon substrate to a second heat treatment.

In the method for fabricating a back electrode type solar cell of the present invention, the temperature of heat treatment at the surface of the silicon substrate is preferably higher than 850° C. in the step of forming a light-receiving face passivation film.

Furthermore, in the method for fabricating a back electrode type solar cell of the present invention, the light-receiving face passivation film is preferably a silicon oxide film.

Furthermore, the method for fabricating a back electrode type solar cell of the present invention preferably includes the step of forming a back face passivation film at a second surface of the silicon substrate at a side opposite to the surface.

Furthermore, in the method for fabricating a back electrode type solar cell of the present invention, the sheet resistance of the light-receiving face diffusion layer is preferably greater than or equal to 100 Ω/□ and less than 250 Ω/□.

Furthermore, in the method for fabricating a back electrode type solar cell of the present invention, the second heat treatment is preferably carried out continuous to the first heat treatment.

In addition, the present invention is directed to a back electrode type solar cell including a first conductivity type silicon substrate, a first conductivity type electrode and a second conductivity type electrode provided at a back face of the silicon substrate located at a side opposite to a light-receiving face, a light-receiving face diffusion layer provided at the light-receiving face of the silicon substrate, a light-receiving face passivation film provided on the light-receiving face diffusion layer, and an anti-reflection film provided on the light-receiving face passivation film. The light-receiving face diffusion layer has a concentration of first conductivity type impurities higher than the concentration of the first conductivity type impurities in the silicon substrate. The sheet resistance of the light-receiving face diffusion layer is greater than or equal to 100 Ω/ [symbol] and less than 250 Ω/ [symbol] . The anti-reflection film is composed of titanium oxide including first conductivity type impurities.

In the back electrode type solar cell of the present invention, the first conductivity type impurities in the anti-reflection film are n type impurities. The n type impurities are preferably present as phosphorus oxide in an amount greater than or equal to 15% by mass and less than or equal to 35% by mass of the anti-reflection film.

### Advantageous Effects of Invention

According to the present invention, there can be provided a method for fabricating a back electrode type solar cell allowing efficient production with a reduced number of steps, and allowing recombination current caused by passivation at the light-receiving face side to be reduced, and a back electrode type solar cell.

### BRIEF DESCRIPTION OF DRAWINGS

FIG. 1 is a schematic plan view of a back face of a back electrode type solar cell according to an embodiment.

FIG. 2 represents the back electrode type solar cell of FIG. 1, wherein (a) is a schematic sectional view taken along II-II of FIG. 1, (b) is a schematic enlarged sectional view of a portion of the light-receiving face of an n type silicon substrate shown in (a), and (c) is an enlarged sectional view schematically depicting the difference in the thickness between the n++ layer and p+ layer shown in (a).

FIG. 3 is a schematic plan view of the back face of an n type silicon substrate when an n type electrode, a p type electrode, and a back face passivation film are removed from the back electrode type solar cell according to the embodiment.

FIG. 4 is a schematic sectional view representing, by (a) to (j), an example of a method for fabricating a back electrode type solar cell according to an embodiment.

FIG. 5 represents a sectional structure of a sample produced by an example.

FIG. 6 is a flowchart of the method for fabricating the sample of FIG. 5.

FIG. 7 represents the relationship between the amount of recombination current and the formation temperature T of a silicon oxide film according to the example.

FIG. 8 represents the relationship between the sheet resistance and the formation temperature T of a silicon oxide film according to the example.

FIG. 9 represents an X-ray diffraction pattern of a titanium oxide film in the sample, wherein (a) corresponds to the example and (b) corresponds to a comparative example.

FIG. 10 is a schematic sectional view of a conventional back electrode type solar cell disclosed in PTD 1.

FIG. 11 is a flowchart of a method for fabricating the back electrode type solar cell of FIG. 10, contemplating the light-receiving face side.

### DESCRIPTION OF EMBODIMENTS

Embodiments of the present invention will be described hereinafter. In the drawings of the embodiment of the present invention, the same reference characters denote the same or corresponding elements.

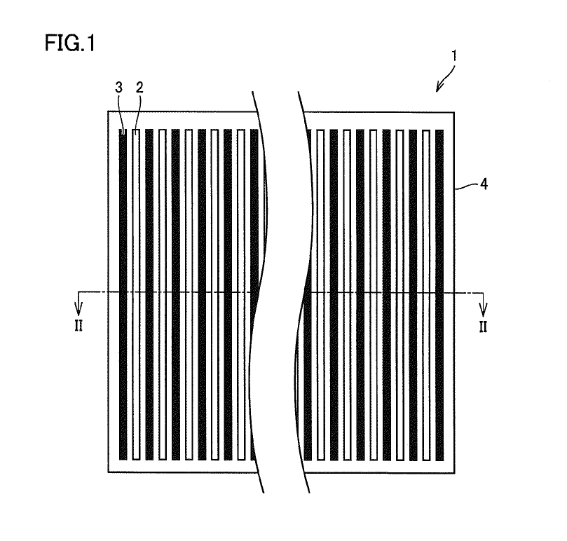

FIG. 1 is a schematic plan view of a back face of a back electrode type solar cell according to an embodiment as an example of a back electrode type solar cell of the present invention. A back electrode type solar cell 1 of FIG. 1 includes a strip n electrode 2 and a strip p electrode 3 at the back face of n type silicon substrate 4 located at the side opposite to the light-receiving face. N type electrode 2 and p type electrode 3 are formed alternately at the back face of n type silicon substrate 4.

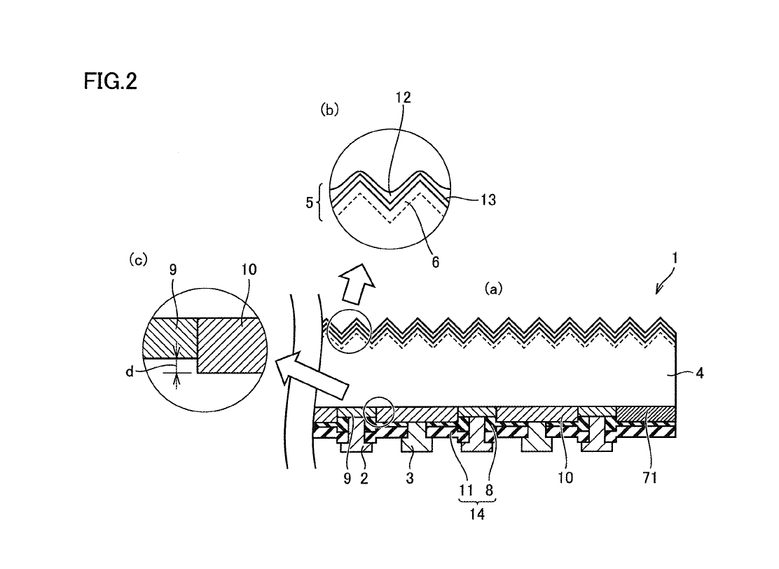

FIG. 2(a) is a schematic sectional view taken along II-II of FIG. 1; FIG. 2(b) is an enlarged sectional view schematically representing a portion of the light-receiving face of an n type silicon substrate 4 shown in FIG. 2(a); and FIG. 2(c) is an enlarged sectional view schematically representing the difference in thickness between an n++ region 9 and a p+ region 10 shown in FIG. 2(a). As shown in (a) and (b) in FIG. 2, a concavo-convex shape 5 (texture structure) is formed at the light-receiving face of n type silicon substrate 4. The concave and convex of concavo-convex shape 5 are set on the order of several μm to several ten μm, for example.

As shown in FIG. 2(b), an n+ region that is a light-receiving face diffusion layer 6 having n type impurities diffused is formed as an FSF layer all over the light-receiving face of n type silicon substrate 4. Light-receiving face diffusion layer 6 has n type conductivity that is identical to the type of n type silicon substrate 4. The concentration of the n type impurities in light-receiving face diffusion layer 6 is higher than the concentration of n type impurities in n type silicon substrate 4.

As shown in FIG. 2(b), a light-receiving face passivation film 13 is formed on light-receiving face diffusion layer 6. Light-receiving face passivation film 13 is formed of a silicon oxide film. The thickness of light-receiving face passivation film 13 can be set to, for example, greater than or equal to 5 nm and less than or equal to 200 nm, preferably greater than or equal to 5 nm and less than or equal to 60 nm.

As shown in FIG. 2(b), an anti-reflection film 12 is formed on light-receiving face passivation film 13. Anti-reflection film 12 includes n type impurities identical in the conductivity type with n type silicon substrate 4, and is formed of a titanium oxide film containing phosphorus as the n type impurities. The thickness of anti-reflection film 12 can be set to, for example, greater than or equal to 10 nm, and less than or equal to 400 nm

The phosphorus in anti-reflection film 12 is present as phosphorus oxide in an amount greater than or equal to 15% by mass and less than or equal to 35% by mass of anti-reflection film 12. Containing an amount greater than or equal to 15% by mass and less than or equal to 35% by mass of anti-reflection film 12 as phosphorus oxide implies that the content of phosphorus oxide in anti-reflection film 12 is 15% by mass to 35% by mass of the entire anti-reflection film 12.

At the back face of n type silicon substrate 4, an n++ region 9 that is an n type semiconductor region and a p+ region 10 that is a p type semiconductor region are formed alternately and adjacent to each other, as shown in FIG. 2(a). This alternate arrangement of n++ region 9 and p+ region 10 in adjacency causes the phenomenon of, when a bias in the reverse direction (reverse bias voltage) is applied to back electrode type solar cell 1, almost no current flows until breakdown voltage, likewise with a general diode, and when a voltage greater than the breakdown voltage is applied, high amperage current (breakdown current) flows without any higher voltage applied to back electrode type solar cell 1. This breakdown current flows to the region where n++ region 9 and p+ region 10 are adjacent at back electrode type solar cell 1, causing current to flow across the entire back face of back electrode type solar cell 1 having n++ region 9 and p+ region 10 arranged alternately and adjacent. Therefore, voltage is not applied partially to back electrode type solar cell 1, allowing heat generated by local leakage current to be impeded.

As shown in FIG. 2(a), at the most outer side of the back side of n type silicon substrate 4, a p+ region 71 that is a p type semiconductor region not in contact with an electrode is formed. Furthermore, the surface of n++ region 9 at the back face of n type silicon substrate 4 is more recessed than the surface of other regions at back face of n type silicon substrate 4. N++ region 9 and p+ region 10 are arranged to constitute a concave.

As shown in FIG. 2(c), the surface of n++ region 9 is located shallower than the surface of p+ region 10 by a depth d. Depth d is set, for example, on the order of several 10 nm. Furthermore, an n type electrode 2 is formed on n++ region 9 and a p type electrode 3 is formed on p+ region 10.

At a portion of the back face of n type silicon substrate 4, a second back face passivation film 8 composed of a silicon oxide film is formed. A first back face passivation film 11 composed of a silicon oxide film, for example, is formed on second back face passivation film 8. This stack of second back face passivation film 8 and first back face passivation film 11 constitutes a back face passivation film 14.

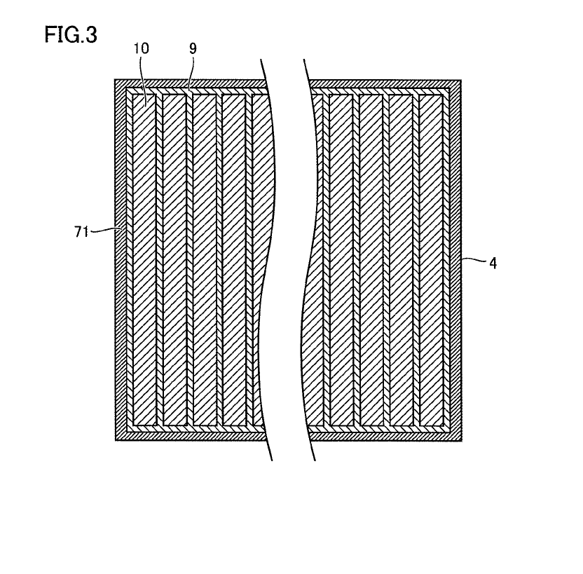

FIG. 3 is a plan view schematically representing the back face of n type silicon substrate 4 when n type electrode 2, p type electrode 3, and back face passivation film 14 are removed from back electrode type solar cell 1. At the circumferential edge at the back face of n type silicon substrate 4, an electrode is not arranged, and a p+ region 71 that is a p type semiconductor region, not in contact with an electrode, is formed (hereinafter, the semiconductor region located at the circumferential edge at the back face of n type silicon substrate 4, and not in contact with the electrode, may also be referred to as “circumferential edge semiconductor region”).

The formation of p+ region 71 that is a circumferential edge semiconductor region so as to surround the perimeter of n++ region 9 at the back face of n type silicon substrate 4 and of a conductivity type differing from that of n++ region 9 is advantageous in that, even when a semiconductor region of a first conductivity type or second conductivity type is formed at the outer side of the region where n++ region 9 and p+ region 10 are formed, the semiconductor region is electrically isolated from n++ region 9 and p+ region 10. Even if bias in the reverse direction (reverse bias voltage) is applied to back electrode type solar cell 1, the generation of leakage current flowing into the electrodes through the circumferential edge of back electrode type solar cell 1 can be suppressed since p+ region 71 that is the circumferential edge semiconductor region is not in contact with the electrode.

Although all n++ regions 9 are joined to constitute one semiconductor region in the example of FIG. 3, necessarily not all n++ regions 9 have to be joined. Furthermore, the structure is not limited to the example shown in FIG. 3 where p+ region 10 is formed separated into a plurality of sections. Some of p+ regions 10 may have joining sections.

Since back electrode type solar cell 1 of the present embodiment has n type electrodes 2 for the electrodes located at either end of the outermost side at the back face of n type silicon substrate 4, the back face of back electrode type solar cell 1 can take a rotationally symmetric structure. Therefore, in the case where a plurality of back electrode type solar cells 1 are to be aligned to produce a solar cell module, the back face of back electrode type solar cell 1 shown in FIG. 1 may have the top side and bottom side inverted.

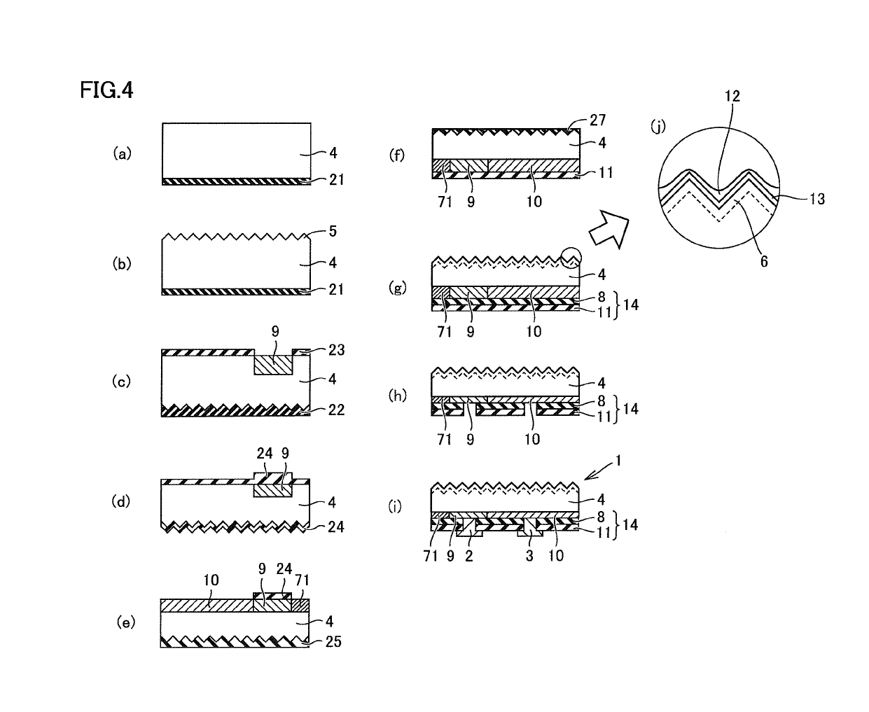

An example of a method for fabricating back electrode type solar cell 1 of the present embodiment will be described with reference to the schematic sectional views of (a) to (j) in FIG. 4.

As shown in FIG. 4(a), a texture mask 21 is formed at the back face located at the side (back face of n type silicon substrate 4) opposite to the side of n type silicon substrate 4 corresponding to the light-receiving face (light-receiving face of n type silicon substrate 4). For n type silicon substrate 4, a substrate composed of n type single crystal silicon having a thickness of 100 μm, for example, may be employed. For texture mask 21, a silicon nitride film, for example, or the like may be employed. Texture mask 21 can be formed by, for example, CVD (Chemical Vapor Deposition), sputtering, or the like.

As shown in FIG. 4(b), concavo-convex shape 5 is formed at the light-receiving face of n type silicon substrate 4. Concavo-convex shape 5 may have a texture structure, for example. Concavo-convex shape 5 can be formed by, for example, etching the light-receiving face of n type silicon substrate 4 with a solution obtained by adding isopropyl alcohol to an alkaline aqueous solution such as an aqueous solution of sodium hydroxide or potassium hydroxide and heated to a temperature greater than or equal to 70° C. and less than or equal to 80° C.

Then, as shown in FIG. 4(c), n++ region 9 is formed at a part of the back face of n type silicon substrate 4. By way of example, n++ region 9 can be formed as set forth below.

First, texture mask 21 located at the back face of n type silicon substrate 4 is removed. Then, a diffusion mask 22 such as a silicon oxide film is formed on the light-receiving face of n type silicon substrate 4. Masking paste is applied to the back face of n type silicon substrate 4 excluding the area where n++ region 9 is to be formed. The masking paste is subjected to a heat treatment to form a diffusion mask 23. By vapor phase diffusion using POCl₃, phosphorus is diffused from diffusion mask 23 to the exposed region at the back face of n type silicon substrate 4 to form n++ region 9.

For the masking paste, paste including a solvent, a thickener, a silicon oxide precursor, for example, may be used. Application of the masking paste may be carried out by, for example, ink jet printing, screen printing, or the like.

As shown in FIG. 4(d), a silicon oxide film 24 is formed at the back face and light-receiving face of n type silicon substrate 4. Silicon oxide film 24 can be formed by, for example, removing diffusion masks 22 and 23 formed at n type silicon substrate 4 as well as a glass layer formed as a result of diffusing phosphorus into diffusion masks 22 and 23 by means of hydrofluoric acid, followed by thermal oxidation with oxygen or water vapor. The thermal oxidation of n type silicon substrate 4 with oxygen or water vapor can be effected by heat treatment with n type silicon substrate 4 placed in an oxygen atmosphere or water vapor atmosphere.

At this stage, as shown in FIG. 4(d), the film thickness of silicon oxide film 24 located on the region where n++ region 9 is formed at the back face of n type silicon substrate 4 (silicon oxide film 24 on n++ region 9) can be set greater than that of silicon oxide film 24 located on a region where n++ region 9 is not formed (silicon oxide film 24 located on a region other than n++ region 9). As an example of silicon oxide film 24 formed in the above-described condition, silicon oxide film 24, when formed by thermal oxidation through water vapor at 900° C., may have a thickness of 250 nm to 350 nm on n++ region 9 and a thickness of 70 nm to 90 nm on a region other than n++ region 9. Here, the phosphorus concentration at the surface of n++ region 9 prior to thermal oxidation is greater than or equal to 5×10¹⁹ atom/cm³. The treatment temperature range of thermal oxidation is 800° C. to 1000° C. for thermal oxidation with oxygen and 800° C. to 950° C. for thermal oxidation with water vapor.

Since the film thickness of the diffusion mask of n++ region 9 at the stage of forming p+ region 10 in the step set forth below is preferably greater than or equal to 60 nm, the difference in thickness between silicon oxide film 24 located on n++ region 9 and silicon oxide film 24 located on a region other than n++ region 9 is preferably greater than or equal to 60 nm.

Further, the deposition rate of silicon oxide film 24 by thermal oxidation can be set different depending upon the type and concentration of impurities diffused at the back face of n type silicon substrate 4 during the formation of silicon oxide film 24 through thermal oxidation. Particularly, when the n type impurity concentration at the back face of n type silicon substrate 4 is high, the deposition rate of silicon oxide film 24 can be increased. Therefore, the film thickness of silicon oxide film 24 located on n++ region 9 having a higher n impurity concentration than n type silicon substrate 4 can be set greater than that of silicon oxide film 24 located on a region other than n++ region 9 having a lower n type impurity concentration than n++ region 9.

Silicon oxide film 24 is formed by the bonding of silicon and oxygen during thermal oxidation.

As shown in FIG. 4(e), p+ region 10 and p+ region 71 are formed at a portion of the back face of n type silicon substrate 4. By way of example, p+ region 10 and p+ region 71 can be formed as set forth below.

First, silicon oxide film 24 located at the light-receiving face of n type silicon substrate 4 and silicon oxide film 24 located on a region other than where n++ region 9 is formed at the back face are removed by etching. Since silicon oxide film 24 located on n++ region 9 at the back face of n type silicon substrate 4 is set greater than the film thickness of silicon oxide film 24 located on a region other than n++ region 9, silicon oxide film 24 located only on n++ region 9 at the back face of n type silicon substrate 4 can be left. By virtue of the difference in the etching rate between silicon oxide film 24 located on n++ region 9 and silicon oxide film 24 located on a region other than n++ region 9, the film thickness of silicon oxide film 24 located on n++ region 9 can be set to approximately 120 nm.

By way of example, in the case where silicon oxide film 24 is formed by thermal oxidation with water vapor at 900° C. for 30 minutes and a hydrofluoric acid treatment is applied for removing silicon oxide film 24 located on a region other than where n++ region 9 is formed, the film thickness of silicon oxide film 24 located on n++ region 9 can be set to approximately 120 nm. When the film thickness of silicon oxide film 24 located on n++ region 9 is greater than or equal to 60 nm, as set forth above, silicon oxide film 24 suitably serves as a diffusion mask for the formation of p+ region 10 and p+ region 71.

Formation of p+ region 10 and p+ region 71 additionally includes the steps of forming a diffusion mask 25 such as a silicon oxide film at the light-receiving face of n type silicon substrate 4, applying to the back face of n type silicon substrate 4 a solution obtained by dissolving a polymer based on reaction of organic polymer with boron compound in an alcohol-based solvent, performing drying, and diffusing boron that is a p type impurity to the exposed region at the back face of n type silicon substrate 4 by heat treatment.

Then, as shown in FIG. 4(f), first back face passivation film 11 is formed at the back face of n type silicon substrate 4. First back face passivation film 11 can be formed as set forth below, by way of example.

First, silicon oxide film 24 and diffusion mask 25 formed at silicon substrate 4 as well as a glass layer formed as a result of diffusing boron to silicon oxide film 24 and diffusion mask 25 are removed by a hydrofluoric acid treatment.

Then, first back face passivation film 11 also serving as a diffusion mask such as a silicon oxide film is formed at the back face of n type silicon substrate 4 by application through CVD or SOG (Spin-On-Glass), firing, and the like.

Then, a liquid mixture 27 including at least a phosphorus compound, titanium alkoxide, and alcohol is applied by spin coating onto the light-receiving face of n type silicon substrate 4, followed by drying. Liquid mixture 27 is applied for the purpose of forming an n+ region relevant to light-receiving face diffusion layer 6 at the light-receiving face of n type silicon substrate 4 and forming a titanium oxide film containing phosphorus relevant to anti-reflection film 12. For a phosphorus compound in liquid mixture 27, phosphorus pentoxide, for example, can be used. For titanium alkoxide, tetraisopropyl titanate, for example, can be used. For the alcohol, isopropyl alcohol, for example, can be used.

Then, as shown in (g) and (j) in FIG. 4, light-receiving face diffusion layer 6 that is an n+ region is formed at the light-receiving face of n type silicon substrate 4, and anti-reflection film 12 is formed on the light-receiving face of n type silicon substrate 4.

Formation of light-receiving face diffusion layer 6 and anti-reflection film 12 is carried out by subjecting liquid mixture 27 applied and dried at the light-receiving face of n type silicon substrate 4 to heat treatment in a nitrogen atmosphere (first heat treatment). By the heat treatment, diffusion of phosphorus that is an n type impurity to the light-receiving face of n type silicon substrate 4 is effected to form light-receiving face diffusion layer 6 all over the light-receiving face of n type silicon substrate 4, and a titanium oxide film containing phosphorus relevant to anti-reflection film 12 is formed on the light-receiving face of n type silicon substrate 4.

The sheet resistance of light-receiving face diffusion layer 6 is preferably greater than or equal to 100 Ω/ [symbol] and less than 250 Ω/ [symbol] . This range allows reduction of recombination current caused by passivation at the light-receiving face side of back electrode type solar cell 1, leading to improvement of the property of back electrode type solar cell 1.

As shown in (g) and (j) of FIG. 4, second back face passivation film 8 is formed at back face of n type silicon substrate 4, and light-receiving face passivation film 13 is formed on light-receiving face diffusion layer 6 at the light-receiving face of n type silicon substrate 4.

Second back face passivation film 8 and light-receiving face passivation film 13 can be formed through thermal oxidation of n type silicon substrate 4 by subjecting n type silicon substrate 4 to heat treatment in, for example, an oxygen atmosphere or water vapor atmosphere (second heat treatment). Accordingly, second back face passivation film 8 composed of a silicon oxide film can be formed between the back face of n type silicon substrate 4 and first back face passivation film 11, as well as light-receiving face passivation film 13 composed of a silicon oxide film between light-receiving face diffusion layer 6 and anti-reflection film 12 at the light-receiving face of n type silicon substrate 4.

The reason why light-receiving face passivation film 13 is formed between light-receiving face diffusion layer 6 and anti-reflection film 12 is possibly because of a crack generated at anti-reflection film 12 due to a thick anti-reflection film 12 at the concave section of concavo-convex shape 5 at the light-receiving face, and oxygen or water vapor entering the region of the crack causes deposition of a silicon oxide film relevant to light-receiving face passivation film 13. Another likely cause is the passage of oxygen or water vapor through the thin anti-reflection film 12 at the convex section of concavo-convex shape located at the light-receiving face, leading to deposition of a silicon oxide film relevant to light-receiving face passivation film 13.

Furthermore, the reason why second back face passivation film 8 is formed between the back face of n type silicon substrate 4 and first back face passivation film 11 is possibly because of first back face passivation film 11 located at the back face of n type silicon substrate 4 being formed by CVD and the like, causing the passage of oxygen or water vapor into first back face passivation film 11, leading to deposition of a silicon oxide film relevant to second back face passivation film 8.

Continuous to the first heat treatment in a nitrogen atmosphere for the formation of light-receiving face diffusion layer 6 and anti-reflection film 12, the gas is switched to preferably carry out a second heat treatment in an oxygen atmosphere or water vapor atmosphere for forming light-receiving face passivation film 13 and second back face passivation film 8. Since no extra step is required to be carried out between the first heat treatment and the second heat treatment in this case, the number of processing steps can be reduced, liable to efficient production of back electrode type solar cell 1.

The heat treatment temperature at the surface of n type silicon substrate 4 during formation of light-receiving face passivation film 13 is preferably higher than 850° C. In this case, recombination current caused by passivation at the light-receiving face side of back electrode type solar cell 1 can be reduced, allowing improvement of the property of back electrode type solar cell 1.

As shown in FIG. 4(h), back face passivation film 14 is partially removed to expose a part of n++ region 9 and a part of p+ region 10 at back face passivation film 14.

This partial removal of back face passivation film 14 can be carried out by heating etching paste applied by screen printing or the like to a part of back face passivation film 14. Then, the etching paste can be removed by oxidation, for example, subsequent to ultrasonic cleaning. The etching paste that can be used includes, for example, at least one selected from the group consisting of phosphoric acid, hydrogen fluoride, ammonium fluoride, and ammonium hydrogen fluoride as an etching component, as well as water, an organic solvent, and a thickener.

As shown in FIG. 4(i), n type electrode 2 is formed on n++ region 9, and p type electrode 3 is formed on p+ region 10.

N type electrode 2 and p type electrode 3 can be formed by applying silver paste at a predetermined position of back face passivation film 14 by screen printing, and drying the silver paste, followed by firing the silver paste. Thus, back electrode type solar cell 1 according to an embodiment can be fabricated.

In the present embodiment, a solution 27 including a phosphorus compound containing phosphorus as n type impurities of a conductivity type identical to that of n type silicon substrate 4, titanium alkoxide and alcohol is applied to one surface of n type silicon substrate 4 employed in back electrode type solar cell 1, followed by heat treatment to form anti-reflection film 12 and light-receiving face diffusion layer 6 that is an FSF layer, as set forth above. Since light-receiving face diffusion layer 6 and anti-reflection film 12 do not have to be formed separately in the present embodiment, the number of processing steps can be reduced to allow efficient production of back electrode type solar cell 1.

Furthermore, since the heat treatment directed to forming light-receiving face diffusion layer 6 and anti-reflection film 12 is carried out in a nitrogen atmosphere in the present embodiment, recombination current caused by passivation at the light-receiving face side of back electrode type solar cell 1 can be reduced, allowing the property of back electrode type solar cell 1 to be improved.

Furthermore, at back electrode type solar cell 1 fabricated as set forth above, the sheet resistance of light-receiving face diffusion layer 6 provided at the light-receiving face of n type silicon substrate 4 is greater than or equal to 100 Ω/ [symbol] and less than 250 Ω/ [symbol] , and anti-reflection film 12 is formed of titanium oxide containing phosphorus.

Therefore, recombination current caused by passivation at the light-receiving face side of back electrode type solar cell 1 can be reduced, allowing the property of back electrode type solar cell 1 to be improved.

Particularly in the case where n type impurities such as phosphorus are present as a phosphorus oxide in an amount greater than or equal to 15% by mass and less than or equal to 35% by mass of anti-reflection film 12, the recombination current caused by passivation at the light-receiving face side of back electrode type solar cell 1 can be further reduced, allowing the property of back electrode type solar cell 1 to be further improved.

### EXAMPLE

<Production of Sample>

FIG. 5 shows a sectional structure of a sample 81 produced in the inventive example. Sample 81 includes an n type silicon substrate 82, an n+ region 83 corresponding to a light-receiving face diffusion layer at both surfaces of n type silicon substrate 82, a silicon oxide film 84 corresponding to a light-receiving face passivation film and back face passivation film on n+ region 83, and a titanium oxide film 85 containing phosphorus, corresponding to an anti-reflection film, on silicon oxide film 84.

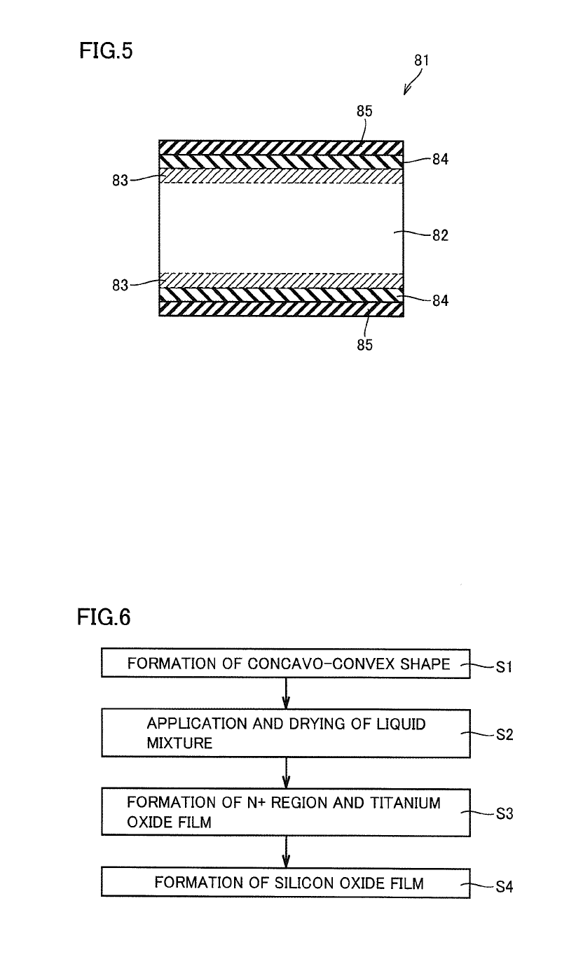

Sample 81 shown in FIG. 5 is produced as set forth below. FIG. 6 is a flowchart of the method for fabricating sample 81 shown in FIG. 5.

As shown in step S1, a concavo-convex shape (not shown in FIG. 5) was formed at each surface of n type silicon substrate 82.

Then, as shown in step S2, a liquid mixture including a phosphorus compound, titanium alkoxide and alcohol was applied onto the concavo-convex shape at both surfaces of n type silicon substrate 82, followed by drying. For a phosphorus compound, phosphorus pentoxide was used. For titanium alkoxide, tetraisopropyl titanate was used. For the alcohol, isopropyl alcohol was used.

As shown in step S3, the liquid mixture located on the concavo-convex shape at both surfaces of n type silicon substrate 82 was subjected to heat treatment to cause diffusion of phosphorus to the surface of n type silicon substrate 82 to form n+ region 83, and to form titanium oxide film 85 containing phosphorus on the surface of n type silicon substrate 82.

As shown in step S4, both surfaces of n type silicon substrate 82 were subjected to heat treatment using oxygen to form silicon oxide film 84 between n+ region 83 and titanium oxide film 85. Thus, sample 81 shown in FIG. 5 was produced.

<Measurement of Recombination Current>

The amount of recombination current of sample 81 produced as set forth above was measured. The recombination current of sample 81 was measured by the QSSPC (Quasi Steady State Photo Conductance) employing WTC-120 that is a product of Sinton Consulting Inc. as a measuring device.

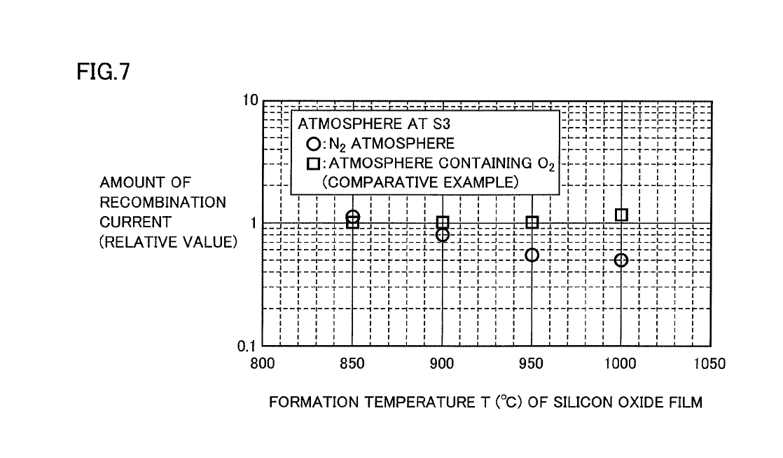

FIG. 7 represents the measurement results of the recombination current of sample 81 with the formation temperature T of silicon oxide film 84 in step S4 altered to 850° C., 900° C., 950° C. and 1000° C. In FIG. 7, the vertical axis represents the amount of recombination current whereas the horizontal axis represents formation temperature T of silicon oxide film 84. In FIG. 7, the recombination current of sample 81 according to the inventive example produced with the heat treatment at step S3 carried out in a nitrogen atmosphere is represented by a circle, whereas the recombination current of sample 81 according to a comparative example produced with the heat treatment at step S3 carried out in an atmosphere containing oxygen is represented by a rectangle. The amount of the recombination current in FIG. 7 is represented by a relative value with 1 as the amount of the recombination current of sample 81 according to the comparative example produced with the heat treatment at step S3 carried out in an atmosphere containing oxygen and formation temperature T of silicon oxide film 84 in step S4 at 850° C.

As shown in FIG. 7, sample 81 according to the inventive example produced with the heat treatment at step S3 carried out in a nitrogen atmosphere exhibited reduction in the amount of recombination current as a function of higher formation temperature T of silicon oxide film 84 in step S4. Additionally, as shown in FIG. 7, sample 81 according to the comparative example produced with the heat treatment at step S3 carried out in an atmosphere containing oxygen could not have the amount of recombination current reduced even if formation temperature T of silicon oxide film 84 in step S4 was altered.

As shown in FIG. 7, the difference in the amount of recombination current between sample 81 of the inventive example and sample 81 of the comparative example was greater as a function of higher formation temperature T for silicon oxide film 84 in step S4.

Furthermore, as shown in FIG. 7, the amount of recombination current of sample 81 according to the inventive example was reduced when formation temperature T of silicon oxide film 84 in step S4 was higher than 850° C. From the standpoint of reducing the amount of recombination current, formation temperature T of silicon oxide film 84 is preferably greater than or equal to 900° C., more preferably greater than or equal to 950° C.

From the results set forth above, it was appreciated that the atmosphere of the heat treatment in step S3 and formation temperature T of silicon oxide film 84 in step S4 greatly affect the amount of recombination current of sample 81.

<Measurement of Sheet Resistance>

Following measurement of the amount of recombination current of sample 81 produced as set forth above, silicon oxide film 84 and titanium oxide film 85 located at both faces of sample 81 were removed, and n+ region 83 located at one face was also removed. The sheet resistance (Ω/□) of n+ region 83 not removed was measured.

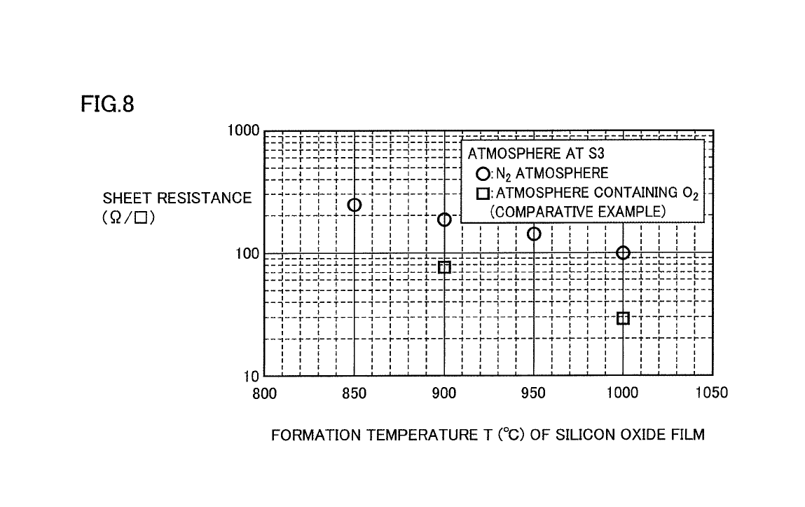

FIG. 8 represents the measurement results of the sheet resistance of sample 81 with formation temperature T of silicon oxide film 84 in step S4 altered to 850° C., 900° C., 950° C. and 1000° C. In FIG. 8, the vertical axis represents the sheet resistance whereas the horizontal axis represents formation temperature T of silicon oxide film 84. Further in FIG. 8, the sheet resistance of sample 81 according to the inventive example produced with the heat treatment at step S3 carried out in a nitrogen atmosphere is represented by a circle, whereas the sheet resistance of sample 81 according to the comparative example produced with the heat treatment at step S3 carried out in an atmosphere containing oxygen is represented by a rectangle.

As shown in FIG. 8, it was appreciated that sample 81 according to the inventive example produced with the heat treatment at step S3 carried out in a nitrogen atmosphere exhibited a lower sheet resistance as compared to sample 81 according to the comparative example produced with the heat treatment at step S3 carried out in an atmosphere containing oxygen. This is possibly due to the segregation of phosphorus that is an n type impurity onto the surface of n type silicon substrate 82 during the heat treatment in an atmosphere containing oxygen. It is thought that the recombination current could not be reduced by the deficiency caused by the segregated phosphorus.

Further, the sheet resistance of n+ region 83 corresponding to the range of formation temperature T of silicon oxide film 84 in step S4 being higher than 850° C. and less than or equal to 1000° C. that has been confirmed to allow the amount of recombination current of sample 81 according to the inventive example to be suitably reduced through the above-described measurement of recombination current was greater than or equal to 100 Ω/ [symbol] and less than 250 Ω/ [symbol] .

<Crystal Structure Analysis of Titanium Oxide Film>

The crystal structure in titanium oxide film 85 of sample 81 according to the inventive example produced with the heat treatment at step S3 carried out in a nitrogen atmosphere and of sample 81 according to the comparative example produced with the heat treatment at step S3 carried out in an atmosphere containing oxygen was analyzed by X-ray diffraction. For sample 81 of the inventive example and comparative example, a sample produced with the heat treatment temperature of 920° C. in step S3 and formation temperature T of silicon oxide film 84 at 950° C. in step S4 was used.

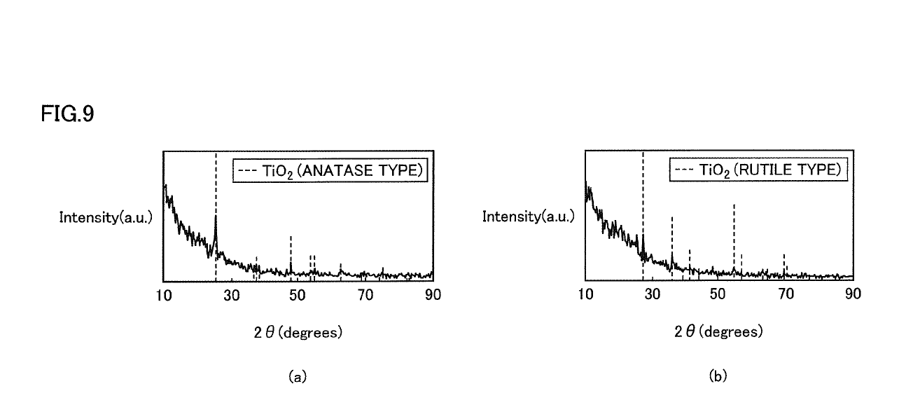

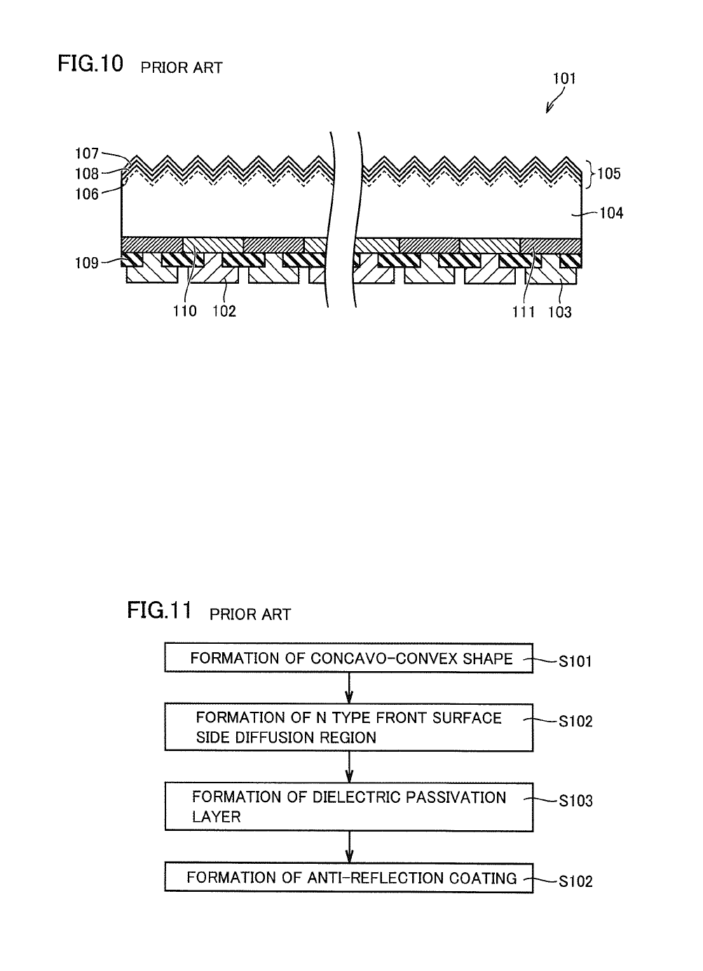

FIG. 9(a) represents the X-ray diffraction pattern of titanium oxide film 85 in sample 81 according to the inventive example. FIG. 9(b) represents the X-ray diffraction pattern of titanium oxide film 85 in sample 81 according to the comparative example.

As shown in FIG. 9(a), titanium oxide film 85 in sample 81 of the inventive example has an anatase type crystal structure. As shown in FIG. 9(b), titanium oxide film 85 in sample 81 of the comparative example had a rutile type crystal structure.

<Results>

It was appreciated from the aforementioned results that, when the heat treatment for forming an n+ region relevant to a light-receiving face diffusion layer and a titanium oxide film containing phosphorus relevant to an anti-reflection film is carried out in a nitrogen atmosphere, the back electrode type solar cell can be fabricated efficiently with the number of processing step reduced, and the amount of recombination current caused by passivation at the light-receiving face side of the back electrode type solar cell can be reduced as compared to the case where the heat treatment was carried out in an atmosphere containing oxygen. Therefore, the property of the back electrode type solar cell can be improved.

Furthermore, by setting the formation temperature of the silicon oxide film relevant to a light-receiving face passivation film higher than 850° C., preferably greater than or equal to 900° C., more preferably greater than or equal to 950° C., the recombination current caused by passivation at the light-receiving face side of the back electrode type solar cell can be further reduced, allowing the property of the back electrode type solar cell to be further improved.

Moreover, in the case where the sheet resistance of the n+ region relevant to a light-receiving face diffusion layer subsequent to formation of a silicon oxide film relevant to a light-receiving face passivation film is greater than or equal to 100 Ω/□ and less than 250 Ω/ [symbol] the recombination current caused by passivation at the light-receiving face side of the back electrode type solar cell can be further reduced, allowing the property of the back electrode type solar cell to be further improved.

Although the above description is based on the case where an n type silicon substrate is employed, a p type silicon substrate may be employed instead. In the case where a p type silicon substrate is employed instead of an n type silicon substrate, the light-receiving face diffusion layer is a p+ region having a p type impurity concentration higher than that of the p type silicon substrate, and the anti-reflection film is a film including p type impurities. The remaining elements of the structure are similar to those set forth above based on an n type silicon substrate.

For the purpose of achieving a larger short-circuit current in the case where a p type silicon substrate is employed, the total area of the n+ region that is a semiconductor region of a conductivity type differing from that of the p type silicon substrate, among the area of the n+ region where an n type electrode is formed and the p++ region where a p type electrode is formed at the back face of the back electrode type solar cell, preferably is larger than the total area of the p++ region. In this case, the p++ region at the back face of the back electrode type solar cell may be separated in a direction perpendicular to the direction of its length. At this stage, an n+ region can be formed between the separated p++ regions. Also in this case, the n+ region may be separated in a direction perpendicular to the direction of its length. At this stage, a p++ region may be formed between the separated n+ regions.

The concept of a back electrode type solar cell according to the present invention is applicable to, not only a back electrode type solar cell having a configuration in which both a p type electrode and an n type electrode are formed at only one surface (back face) of the semiconductor substrate, but also to a solar cell having a MWT (Metal Wrap Through) type configuration (a solar cell having a configuration in which an electrode is partially arranged in a through hole provided at the semiconductor substrate).

Although the present invention has been described based on embodiments and examples, it is initially intended that the above-described features of the embodiments and examples may be combined appropriately.

It should be understood that the embodiments and example disclosed herein are illustrative and nonrestrictive in every respect. The scope of the present invention is defined by the terms of the claims, rather than the description above, and is intended to include any modification within the scope and meaning equivalent to the terms of the claims.

### INDUSTRIAL APPLICABILITY

A method for fabricating a back electrode type solar cell and a back electrode type solar cell according to the present invention can be applied widely to a general method for fabricating a back electrode type solar cell and a back electrode type solar cell.

### REFERENCE SIGNS LIST

1, 14 back electrode type solar cell; 2 n type electrode; 3 p type electrode; 4 n type silicon substrate; 5 concavo-convex shape; 6 light-receiving face diffusion layer; 8 second back face passivation film; 9 n++ region; 10 p+ region; 11 first back face passivation film; 12 anti-reflection film; 13 light-receiving face passivation film; 14 back face passivation film; 21 texture mask; 22, 23, 25 diffusion mask; 24 silicon oxide film; 27 solution; 71 p+ region; 81 sample; 82 n type silicon substrate; 83 n+ region; 84 silicon oxide film; 85 titanium oxide film; 101 back electrode type solar cell; 102 n type metal contact; 103 p type metal contact; 104 n type silicon wafer; 105 concavo-convex shape; 106 n type front surface side diffusion region; 107 anti-reflection coating; 108 dielectric passivation layer; 109 oxide layer; 110 n+ region; 110 p+ region.

1. A method for fabricating a back electrode type solar cell comprising the steps of:
applying a solution including a compound containing first conductivity type impurities, titanium alkoxide, and alcohol to one surface of a first conductivity type silicon substrate,
forming a light-receiving face diffusion layer at said surface of said silicon substrate and forming an anti-reflection film on said surface of said silicon substrate by subjecting said solution to a first heat treatment in a nitrogen atmosphere, and
forming a light-receiving face passivation film on said surface of said silicon substrate by subjecting said surface of said silicon substrate to a second heat treatment.

2. The method for fabricating a back electrode type solar cell according to claim 1, wherein, in said step of forming a light-receiving face passivation film, a temperature of heat treatment at said surface of said silicon substrate is higher than 850° C.

3. The method for fabricating a back electrode type solar cell according to claim 1, wherein said light-receiving face passivation film is a silicon oxide film.

4. The method for fabricating a back electrode type solar cell according to claim 1, further comprising the step of forming a back face passivation film at a second surface of said silicon substrate at a side opposite to said surface.

5. The method for fabricating a back electrode type solar cell according to claim 1, wherein a sheet resistance of said light-receiving face diffusion layer is greater than or equal to 100 Ω/ and less than 250 Ω/.

6. The method for fabricating a back electrode type solar cell according to claim 1, wherein said second heat treatment is carried out continuous to said first heat treatment.

7. A back electrode type solar cell comprising:
a first conductivity type silicon substrate,
a first conductivity type electrode and a second conductivity type electrode provided at a back face of said silicon substrate at a side opposite to a light-receiving face,
a light-receiving face diffusion layer provided at said light-receiving face of said silicon substrate,
a light-receiving face passivation film provided on said light-receiving face diffusion layer, and
an anti-reflection film provided on said light-receiving face passivation film,
said light-receiving face diffusion layer having a concentration of first conductivity type impurities higher than the concentration of first conductivity type impurities in said silicon substrate,
said light-receiving face diffusion layer having a sheet resistance greater than or equal to 100 Ω/ and less than 250 Ω/, and
said anti-reflection film composed of titanium oxide containing first conductivity type impurities.

8. The back electrode type solar cell according to claim 7, wherein
said first conductivity type impurities in said anti-reflection film are n type impurities, and
said n type impurities are present as phosphorus oxide in an amount greater than or equal to 15% by mass and less than or equal to 35% by mass of said anti-reflection film.
